(19) United States
(12) Patent Application Publication
(10) Pub. No.: US 2024/0088190 A1
(43) Pub. Date: Mar. 14, 2024

(54) PHOTOELECTRIC CONVERSION APPARATUS, DEVICE, AND METHOD FOR MANUFACTURING PHOTOELECTRIC CONVERSION APPARATUS

(71) Applicant: CANON KABUSHIKI KAISHA, Tokyo (JP)

(72) Inventor: TAKUYA HARA, Kanagawa (JP)

(21) Appl. No.: 18/450,541

(22) Filed: Aug. 16, 2023

(30) Foreign Application Priority Data
Sep. 8, 2022 (JP) 2022-143101

(51) Int. Cl. H01L 27/146

(52) U.S. Cl. CPC H01L 27/14636; H01L 27/14687

(57) ABSTRACT

A photoelectric conversion apparatus is provided. The apparatus includes a semiconductor layer that includes a pixel region in which a plurality of pixels each including a photoelectric conversion element are arranged. A plurality of wiring layers are arranged on a side of a main surface on the opposite side to a light receiving surface of the semiconductor layer, and a plurality of wiring patterns are arranged in a wiring layer closest to the main surface among the plurality of wiring layers. A pattern density of the wiring patterns arranged in a peripheral region between the pixel region and an outer edge of the semiconductor layer among the plurality of wiring patterns is 35% or more in an arbitrary 100 μm² region of the peripheral region.

### BACKGROUND OF THE INVENTION

### Field of the Invention

The present invention relates to a photoelectric conversion apparatus, a device, and a method for manufacturing a photoelectric conversion apparatus.

### Description of the Related Art

In a photoelectric conversion apparatus such as an image sensor, a back-illuminated photoelectric conversion apparatus may be used for miniaturization and multifunctionality. Japanese Patent Laid-Open No. 2018-088488 describes a back-illuminated sensor chip in which an avalanche photodiode element is provided for each pixel.

### SUMMARY OF THE INVENTION

When forming a back-illuminated photoelectric conversion apparatus, a semiconductor layer in which pixels are arranged is thinned, and a light receiving surface is formed. In order to improve the characteristics of the photoelectric conversion apparatus, it is necessary to improve the flatness of the light receiving surface and the uniformity of the film thickness of the semiconductor layer when the semiconductor layer is thinned.

Some embodiments of the present invention provide a technique that is advantageous for improving the characteristics of a photoelectric conversion apparatus.

According to some embodiments, a photoelectric conversion apparatus comprising a semiconductor layer that includes a pixel region in which a plurality of pixels each comprising a photoelectric conversion element are arranged, wherein a plurality of wiring layers are arranged on a side of a main surface on the opposite side to a light receiving surface of the semiconductor layer, a plurality of wiring patterns are arranged in a wiring layer closest to the main surface among the plurality of wiring layers, and a pattern density of the wiring patterns arranged in a peripheral region between the pixel region and an outer edge of the semiconductor layer among the plurality of wiring patterns is 35% or more in an arbitrary 100 μm² region of the peripheral region, is provided.

According to some other embodiments, a method for manufacturing a photoelectric conversion apparatus, the method comprising: preparing a semiconductor layer comprising a pixel region in which a plurality of pixels each including a photoelectric conversion element are arranged; thinning the semiconductor layer from a side of a light receiving surface on an opposite side to a main surface where a plurality of wiring layers are arranged, wherein a plurality of wiring patterns are arranged in a wiring layer closest to the main surface among the plurality of wiring layers, in the thinning, a film thickness of the semiconductor layer is measured by using reflected light of light irradiated onto the light receiving surface, and a pattern density of the wiring patterns arranged in a peripheral region between the pixel region and an outer edge of the semiconductor layer among the plurality of wiring patterns is 35% or more in an arbitrary 100 μm² region of the peripheral region, is provided.

Further features of the present invention will become apparent from the following description of exemplary embodiments (with reference to the attached drawings).

### BRIEF DESCRIPTION OF THE DRAWINGS

FIG. 1 is a diagram illustrating a cross-sectional configuration example of a photoelectric conversion apparatus according to the present embodiment.

FIG. 2 is a diagram illustrating a planar configuration example of a photoelectric conversion apparatus of FIG. 1.

FIGS. 3A and 3B are diagrams illustrating an effect of the photoelectric conversion apparatus of FIG. 1.

FIG. 4 is a diagram illustrating a relationship between pattern density and erroneous detection occurrence probability.

FIG. 5 is a diagram illustrating an example of arrangement of wiring patterns of the photoelectric conversion apparatus of FIG. 1.

FIG. 6 is a diagram illustrating an example of arrangement of wiring patterns of the photoelectric conversion apparatus of FIG. 1.

FIG. 7 is a diagram illustrating a relationship between a distance between an input/output terminal and a wiring pattern and an erroneous detection occurrence probability.

FIG. 8 is a diagram illustrating an example of arrangement of wiring patterns of the photoelectric conversion apparatus of FIG. 1.

FIG. 9 is a diagram illustrating an example of arrangement of wiring patterns of the photoelectric conversion apparatus of FIG. 1.

FIGS. 10A and 10B are diagrams illustrating examples of arrangement of wiring patterns of the photoelectric conversion apparatus of FIG. 1.

FIG. 11 is a diagram illustrating an example of a configuration of a device in which the photoelectric conversion apparatus of FIG. 1 is incorporated.

FIG. 12 is a diagram for explaining control of the film thickness in a thinning process.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

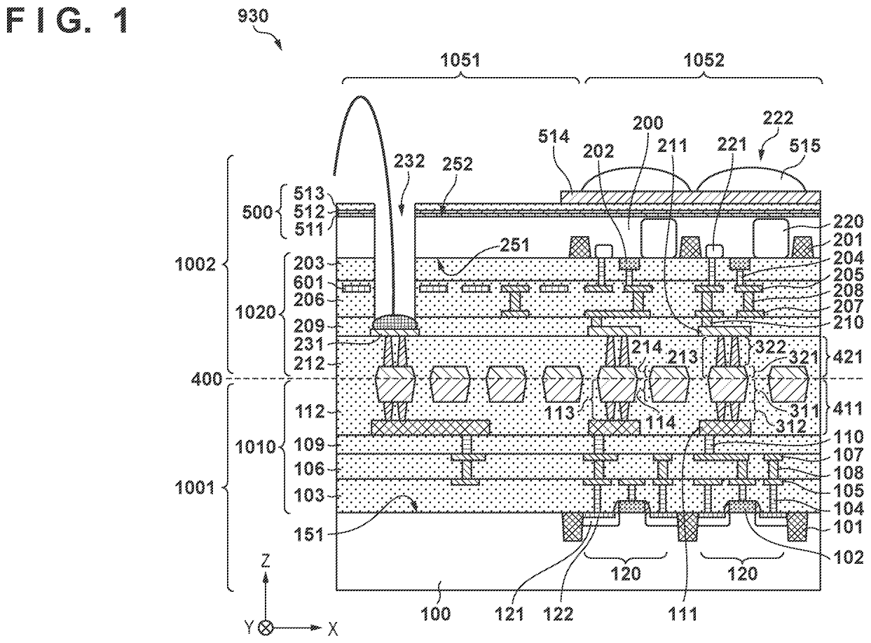

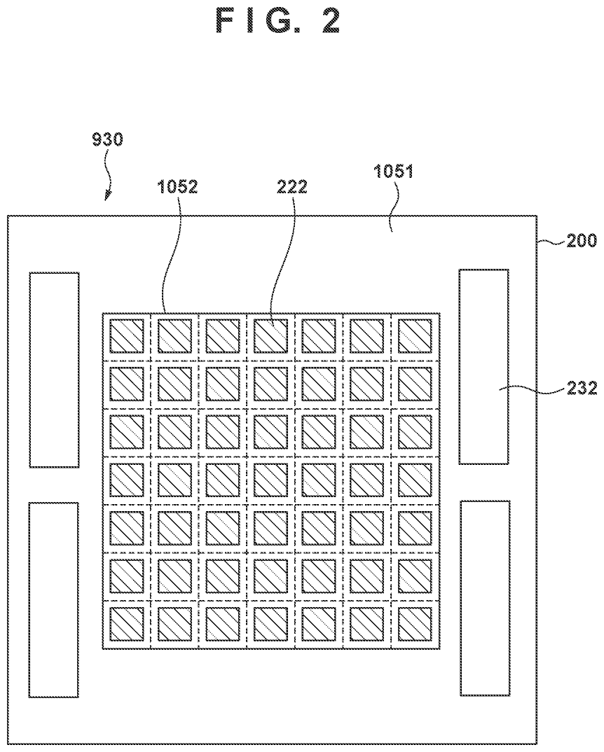

With reference to FIG. 1 to FIG. 12, a photoelectric conversion apparatus and a manufacturing method therefor according to embodiments of the present disclosure will be described. FIG. 1 is a cross-sectional view illustrating a configuration example of a photoelectric conversion apparatus 930 according to the present embodiment. FIG. 2 is a plan view illustrating a configuration example of the photoelectric conversion apparatus 930. The photoelectric conversion apparatus 930 includes a semiconductor layer 200 including a pixel region 1052 in which a plurality of pixels each including a photoelectric conversion element 222 are arranged. Further, the photoelectric conversion apparatus 930 includes a semiconductor layer 100 stacked on the semiconductor layer 200 and in which a plurality of transistors 120 for operating the photoelectric conversion elements 222 are arranged. A semiconductor such as silicon is used for the semiconductor layer 100 and the semiconductor layer 200.

A wiring structure 1010 is arranged on a main surface 151 of the semiconductor layer 100 located on the semiconductor layer 200 side, and constitutes a semiconductor component 1001 together with the semiconductor layer 100, the transistors 120 arranged on the main surface 151 of the semiconductor layer 100, and the like. A wiring structure 1020 including a plurality of wiring layers is arranged on the side of a main surface 251 of the semiconductor layer 200 located on the semiconductor layer 100 side, and constitutes a semiconductor component 1002 together with the semiconductor layer 200 and the like. The main surface 251 of the semiconductor layer 200 is the surface of the semiconductor layer 200 opposite to a light receiving surface 252. The light receiving surface 252 is also a light receiving surface of the photoelectric conversion apparatus 930.

In this embodiment, the semiconductor layer 200 has a thickness of, for example, about 3 to 9 μm. The semiconductor component 1001 and the semiconductor component 1002 overlap each other and are bonded to each other at a bonding interface 400. In the Z direction in which the semiconductor layer 100 and the semiconductor layer 200 are stacked, an insulating film 112 of the semiconductor component 1001 (the wiring structure 1010) and an insulating film 212 of the semiconductor component 1002 (the wiring structure 1020) are stacked so as to be positioned between the semiconductor layer 100 and the semiconductor layer 200. In the wiring structure 1010, each of a plurality of conductive portions 113 is arranged in a respective one of a plurality of recesses provided in the insulating film 112. In the wiring structure 1020, each of a plurality of conductive portions 213 is arranged in a respective one of a plurality of recesses provided in the insulating film 212. The semiconductor component 1001 and the semiconductor component 1002 are bonded to each other by the conductive portions 113 arranged in the recesses provided in the insulating film 112 and the conductive portions 213 arranged in the recesses provided in the insulating film 212.

A plane intersecting the Z direction is defined as an X-Y plane. The Z direction and X-Y plane may intersect orthogonally. The X-Y plane may be a surface parallel to at least one of the main surface 151 of the semiconductor layer 100 and the main surface 251 of the semiconductor layer 200. An X direction and a Y direction may be orthogonal to each other, parallel to at least one of the main surface 151 of the semiconductor layer 100 and the main surface 251 of the semiconductor layer 200. FIG. 1 illustrates a view in which the photoelectric conversion apparatus 930 is cut in a direction (direction Z) in which the semiconductor layer 100 and the semiconductor layer 200 are stacked.

The conductive portions 213 include a pad 321 surrounded by the insulating film 212 in the X-Y plane, and a plug 322 coupled to the pad 321 so as to be positioned between the pad 321 and the semiconductor layer 200 in the Z direction. The plug 322 is connected to a conductive layer 211 located between the plug 322 and the semiconductor layer 200 in the Z direction. The conductive layer 211 is proximate to the plug 322.

The semiconductor component 1001 is a semiconductor component (semiconductor chip) including the semiconductor layer 100 and the wiring structure 1010. The semiconductor component 1002 is a semiconductor component (semiconductor chip) including the semiconductor layer 200 and the wiring structure 1020. The wiring structure 1010 and the wiring structure 1020 each include a plurality of stacked wiring layers and a plurality of stacked insulating films, as will be described later. Therefore, the structure in which the wiring structure 1010 and the wiring structure 1020 are bonded to each other may be referred to as the wiring structure portion in the photoelectric conversion apparatus 930. The photoelectric conversion apparatus 930 is configured by bonding the semiconductor component 1001 and the semiconductor component 1002.

The structure between the semiconductor layer 100 and the semiconductor component 1002 (between the semiconductor layer 100 and the wiring structure 1020) is the wiring structure 1010. The wiring structure 1010 includes the conductive portions 113 described above and a conductive layer 111. The wiring structure 1010 may include, in addition to the conductive portions 113 and the conductive layer 111, plugs 110, a wiring layer 107, plugs 108, a wiring layer 105, plugs 104, and the like arranged between the conductive layer 111 and the semiconductor layer 100. In addition, the wiring structure 1010 may include the insulating film 112 described above, and, in addition to the insulating film 112, may include the insulating films 109, 106, and 103 arranged between the insulating film 112 and the semiconductor layer 100. However, the configuration of the wiring structure 1010 is not limited to the structure illustrated in FIG. 1, and the numbers and arrangement of the wiring layers, the plugs, and the insulating films may be appropriately adjusted according to the function and the performance required for the photoelectric conversion apparatus 930.

The structure between the semiconductor layer 200 and the semiconductor component 1001 (between the semiconductor layer 200 and the wiring structure 1010) is the wiring structure 1020. The wiring structure 1020 includes the conductive portions 213 described above and the conductive layer 211. The wiring structure 1020 may include, in addition to the conductive portions 213 and the conductive layer 211, plugs 210, a wiring layer 207, plugs 208, a wiring layer 205, plugs 204, and the like arranged between the conductive layer 211 and the semiconductor layer 200. In addition, the wiring structure 1020 may include the insulating film 212 described above, and, in addition to the insulating film 212, may include the insulating films 209, 206, and 203 arranged between the insulating film 212 and the semiconductor layer 200. However, the configuration of the wiring structure 1020 is not limited to the structure illustrated in FIG. 1, and the numbers and arrangement of the wiring layers, the plugs, and the insulating films may be appropriately adjusted according to the function and the performance required for the photoelectric conversion apparatus 930. The thickness of the wiring structure 1020 is, for example, greater than 10 μm.

The conductive layers 111 and 211 may be referred to as wiring layers, but in this example, the wiring layers adjacent to plugs 312 and 322 are referred to as conductive layers 111 and 211 in order to distinguish them from other wiring layers. The plug 208 connects the wiring layer 205 and the wiring layer 207, and the plug 210 connects the wiring layer 207 and the conductive layer 211. The conductive portion 213 may have a damascene structure embedded in a recess provided in the insulating film 212. At least a portion of the conductive portion 213 is connected to the conductive layer 211. In the present embodiment, the conductive portion 213 has a dual damascene structure and includes the pad 321 and the plug 322. The semiconductor component 1001 and the semiconductor component 1002 are electrically connected by the conductive portions 113 and the conductive portions 213.

A plurality of wiring patterns 601 are arranged in the wiring layer 205 which is the closest to the main surface 251 of the semiconductor layer 200 among the plurality of wiring layers 205 and 207 arranged in the wiring structure 1020. In this embodiment, the pattern density of the wiring patterns 601 arranged in a peripheral region 1051 between the pixel region 1052 and the outer edge of the semiconductor layer 200 among the plurality of wiring patterns 601 is 35% or more in an arbitrary 100 μm² region of the peripheral region 1051. Details of the pattern density of the wiring patterns 601 will be described later.

The main components of the conductive portion 113 and the conductive portion 213 may be copper, but the present invention is not limited thereto, and the main components of the conductive portion 113 and the conductive portion 213 may be gold or silver. The main components of the insulating film 112 and the insulating film 212 may be silicon compounds such as silicon oxide, silicon nitride, and silicon oxynitride. In addition, the insulating film 112 and the insulating film 212 may have a multi-layer structure made of a plurality of materials, such as a stacked structure in which a layer (for example, a silicon nitride layer) that suppresses metallic diffusion and a silicon oxide layer or a low-k material layer are stacked. By arranging a layer that suppresses diffusion of metal, it is possible to suppress the influence of diffusion of metal caused by a bonding deviation between the conductive portion 113 and the conductive portion 213 caused by alignment deviation or the like occurring at the time of bonding the semiconductor component 1001 and the semiconductor component 1002. Further, for example, the main components of the insulating film 112 and the insulating film 212 may be resin.

Here, the conductive portions 113 and the insulating film 112 are collectively referred to as a bonding member 411, and the conductive portions 213 and the insulating film 212 are collectively referred to as a bonding member 421. The bonding member 411 included in the semiconductor component 1001 is bonded to the bonding member 421 included in the semiconductor component 1002. From the semiconductor layer 100 to the semiconductor layer 200, the plug 104, the wiring layers 105 and 107, the conductive layer 111, the conductive portions 113 and 213, the conductive layer 211, the wiring layers 207 and 205, and the plug 204 are electrically continuous. These constitute a conductive pattern (inter-layer wiring pattern) between the semiconductor layer 100 and the semiconductor layer 200. For example, one end of the inter-layer wiring pattern may be connected to the gate electrode of the transistor 120, and the other end thereof may be connected to the source/drain of the transistor 120. Further, for example, one end and the other end of the inter-layer wiring pattern may be connected to the source/drain of the transistor 120.

In the photoelectric conversion apparatus 930, the wiring structure 1010 and the wiring structure 1020 are bonded to each other. More specifically, the wiring structure 1010 and the wiring structure 1020 are bonded at the bonding interface 400 formed by the bonding member 411 of the wiring structure 1010 and the bonding member 421 of the wiring structure 1020. The bonding interface 400 includes a surface of the bonding member 411 and a surface of the bonding member 421.

An element isolation portion 101 and the plurality of transistors 120 are provided on the main surface 151 of the semiconductor layer 100. The main surface 151 of the semiconductor layer 100 may be referred to as the surface of the semiconductor layer 100. In the photoelectric conversion apparatus 930, an integrated circuit including the transistors 120 arranged in the semiconductor layer 100 may include a signal processing circuit such as an analog signal processing circuit, an A/D conversion circuit, a noise removing circuit, or a digital signal processing circuit that processes a signal outputted from the photoelectric conversion elements 222. That is, at least some of the plurality of transistors 120 may constitute a digital signal processing circuit for digitally processing signals output from the plurality of photoelectric conversion elements 222 of the semiconductor layer 200. Further, the semiconductor layer 100 may be referred to as a “semiconductor substrate”.

The element isolation portion 101 may have a shallow trench isolation (STI) configuration, and define element regions (active regions) of the semiconductor layer 100. The plurality of transistors 120 may constitute, for example, a CMOS circuit. The source/drain 121 of the transistor 120 may comprise a silicide layer 122, such as cobalt silicide or nickel silicide. Therefore, the conductive portion 113 is electrically connected to the semiconductor layer 100 via the silicide layer 122. More specifically, the plug 104 which is electrically connected to the conductive portion 113 is in contact with the silicide layer 122 formed between the interlayer insulating film 103 and the semiconductor layer 100 through a salicide process or the like. When the conductive portion 113 is electrically connected to the semiconductor layer 100 via the silicide layer 122, the contact resistance may be lower than when the conductive portion 113 is electrically connected to the semiconductor layer 100 without the silicide layer. A gate electrode 102 of the transistor 120 may include a silicide layer, a metal layer, and a metal compound layer. As the gate insulating film of the transistor 120, in addition to silicon oxide, silicon nitride, or the like, a metal oxide such as hafnium oxide or the like may be used.

On the main surface 251 of the semiconductor layer 200, an element isolation portion 201, gate electrodes 202, photoelectric conversion portions 220, a floating diffusion 221, and the like are provided. The photoelectric conversion portion 220 includes a photodiode and a photogate. The photodiode may be an avalanche photodiode. The main surface of the semiconductor layer 200 on which a plurality of transistors are provided is the main surface 251 of the semiconductor layer 200. The main surface 251 of the semiconductor layer 200 may be referred to as the surface of the semiconductor layer 200. As described above, the main surface of the semiconductor layer 200 opposite to the main surface 251 is the light receiving surface 252 on which light is incident in the photoelectric conversion apparatus 930. Further, the semiconductor layer 200 may be referred to as a “semiconductor substrate”.

The element isolation portion 201 has, for example, an STI structure and defines element regions (active regions) of the semiconductor layer 200. The gate electrode 202 transfers the electric charge of the photoelectric conversion portion 220 to the floating diffusion 221. The semiconductor layer 200 may also be provided with a pixel circuit that converts the electric charge generated by the photoelectric conversion portion 220 into a pixel signal. The pixel circuit may include a reset transistor, an amplification transistor, a selection transistor, and the like. A pixel signal corresponding to the electric charge transferred to the floating diffusion 221 is generated by the amplification transistor. The potential of the floating diffusion 221 is reset to the reset potential by the reset transistor. The photoelectric conversion element 222 described above may include the photoelectric conversion portion 220, the gate electrode 202, the floating diffusion 221, and a pixel circuit thereof.

The conductive portion 113 is electrically connected to the semiconductor layer 100 via the silicide layer 122, as described above. Meanwhile, the conductive portion 213 is electrically connected to the semiconductor layer 200 without going through the silicide layer. In the present embodiment, the plug 204 electrically connected to the conductive portion 213 is in contact (ohmic contact) with an impurity region of the semiconductor layer 200 formed without going through a salicide process. However, the present invention is not limited thereto, and the plug 204 may be electrically connected to the semiconductor layer 200 via a silicide layer such as titanium silicide or tungsten silicide locally formed under the plug 204.

In the present embodiment, the semiconductor component 1001 includes a digital circuit and the semiconductor component 1002 includes an analog circuit, but the semiconductor component 1001 may include an analog circuit and the semiconductor component 1002 may include a digital circuit. The photoelectric conversion portion 220 provided in the semiconductor layer 200 is connected to the floating diffusion 221 via the gate electrode 202. The floating diffusion 221 is connected to the gate electrode of a source follower transistor of the above-described pixel circuit. An analog pixel signal is output from the source of the source follower transistor. The pixel circuit including the gate electrode 202 and the source follower transistor may be an analog circuit included in the semiconductor component 1002. The analog pixel signal is A/D converted into a digital pixel signal by an A/D conversion circuit. The digital pixel signal is processed by a digital signal processing circuit (DSP). The digital signal processing circuit, which performs image processing, may be an image processing circuit (ISP). The digital signal processing circuit may be a circuit arranged in the semiconductor component 1001. Other examples of a digital circuit arranged in the semiconductor component 1002 include an interface circuit for low voltage differential signaling (LVDS), a mobile industry processor interface (MIPI), and the like.

In the photoelectric conversion apparatus 930 of the present embodiment, a dielectric film 500 including a dielectric 511, a dielectric 512, and a dielectric 513 is arranged on the light receiving surface 252 of the semiconductor layer 200. The dielectric film 500 may have a stacked structure including the plurality of dielectrics 511 to 513 as illustrated in FIG. 1, or may have a single-layer structure.

As the dielectric 511, a metal oxide having a negative fixed charge may be used. By arranging the dielectric 511 having a negative fixed charge in the vicinity of the semiconductor layer 200, noise caused by electronics generated in the vicinity of the semiconductor layer 200 can be reduced. As the dielectric 511 having a negative fixed charge, for example, a material such as hafnium oxide, aluminum oxide, zirconium oxide, titanium oxide, tantalum oxide, or ruthenium oxide is used. For example, the dielectric 511 may be hafnium oxide or aluminum oxide. The thickness of the dielectric 511 may be, for example, 5 nm to 20 nm. In the configuration illustrated in FIG. 1, the dielectric 511 is arranged so as to cover the light receiving surface 252 of the semiconductor layer 200, and the dielectric 511 is in contact with the semiconductor layer 200. However, the present invention is not limited thereto, and another dielectric having a thickness less than 10 nm may be arranged between the dielectric 511 and the light receiving surface 252 of the semiconductor layer 200. For example, silicon oxide of less than 10 nm may be arranged between the dielectric 511 which is formed of hafnium oxide or the like and the light receiving surface 252 of the semiconductor layer 200.

The dielectric 512 may function as an antireflection layer. When the dielectric 512 is used as an antireflection layer, the thickness of the dielectric 512 may be greater than the thickness of the dielectric 511. When the dielectric 512 is used as an antireflection layer, the thickness of the dielectric 512 may be, for example, within 20 nm to 100 nm. As the dielectric 512, a metal oxide layer such as hafnium oxide, aluminum oxide, zirconium oxide, titanium oxide, tantalum oxide, or ruthenium oxide may be used. In addition, a silicon compound such as silicon oxide, silicon nitride, or silicon oxynitride may be used for the dielectric 512. Since tantalum oxide has the highest dielectric constant among these dielectrics, tantalum oxide may be used for the dielectric 512 that functions as an antireflection layer.

For the dielectric 513, a material having a lower refractive index than the dielectric 512 is used to provide the dielectric 512 with appropriate antireflection performance. As the dielectric 513, a silicon compound such as silicon oxide, silicon nitride, or silicon oxynitride may be used, or a resin material may be used.

A color filter 514 and microlenses 515 are arranged on the dielectric film 500. Further, for example, a light-shielding film for forming optical black (OB) regions may be provided between the dielectric film 500 and the color filter 514 and the microlens 515 using a metal such as tungsten. Further, for example, the dielectric film 500 or the color filter 514 may be provided with a light shielding wall for separating light between the photoelectric conversion elements 222.

FIG. 2 is a plan view of the photoelectric conversion apparatus 930 viewed from the side of the light receiving surface 252 of the semiconductor layer 200. As illustrated in FIG. 2, the pixel region 1052 in which a plurality of pixels each including a photoelectric conversion element 222 are arranged may be arranged in a central portion of the semiconductor layer 200. The peripheral region 1051 is arranged between the pixel region 1052 and the outer edge of the semiconductor layer 200. As illustrated in FIG. 1, a plurality of input/output terminals 231 for electrically connecting the photoelectric conversion apparatus 930 and an external device (not illustrated) are arranged in the peripheral region 1051. Further, in the semiconductor layer 200, a plurality of openings 232 for exposing the plurality of input/output terminals 231 are arranged. One input/output terminal may be arranged in one opening 232, or a plurality of input terminals may be arranged in one opening. In the present embodiment, the input/output terminals 231 are provided using the conductive layer 211, but the present invention is not limited thereto. The input/output terminals 231 may be arranged using other wiring layers 205 and 207 or conductive layers disposed in the wiring structure 1020. Further, for example, the input/output terminals 231 may be provided using the wiring layers 105 and 107 and the conductive layer 111 of the wiring structure 1010. The openings 232 are arranged in the wiring structure 1020 (possibly the wiring structure 1010) so as to extend through the semiconductor layer 200 and expose the input/output terminals 231.

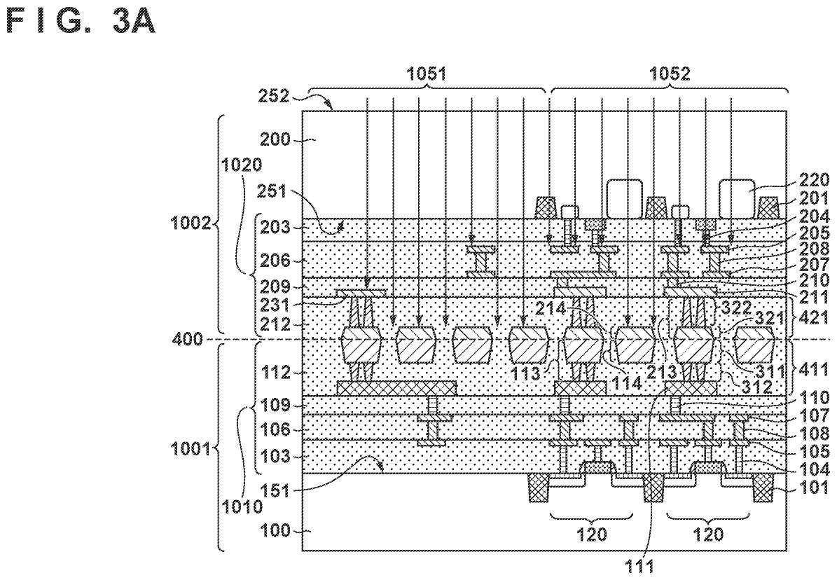

Next, an advantage of the present embodiment will be described with reference to FIG. 3A to FIG. 5. When manufacturing the photoelectric conversion apparatus 930, first, the semiconductor component 1001 including the semiconductor layer 100 in which the transistors 120 and the like are arranged and the semiconductor component 1002 including the semiconductor layer 200 including the pixel region 1052 as described above are prepared. Next, the semiconductor component 1001 and the semiconductor component 1002 are bonded to each other via the bonding interface 400. After the bonding the semiconductor component 1001 and the semiconductor component 1002, a process of thinning the semiconductor layer 200 from the side of the light receiving surface 252 opposite to the main surface 251 where the plurality of wiring layers 205 and 207 are arranged is performed. By this thinning process, the light receiving surface 252 of the semiconductor layer 200 becomes the light receiving surface of the photoelectric conversion apparatus 930.

In the process of thinning the semiconductor layer 200, for example, machine grinding is performed while measuring the film thickness of the semiconductor layer 200 using reflected light of light irradiated onto the light receiving surface 252 of the semiconductor layer 200. That is, the semiconductor layer 200 is thinned while the film thickness of the semiconductor layer 200 is monitored according to a reflection spectrum of the light entering from the light receiving surface 252 of the semiconductor layer 200 and reflected by the wiring layers 205 and 207, the conductive layers 211 and 214, and the like. Thereby, the flatness of the light receiving surface 252 and the film thickness uniformity of the semiconductor layer 200 can be determined. Here, the thinning process is not limited to the machine grinding method, and a CMP method or a wet etching method may be used. In either method, the thickness of the semiconductor layer 200 is measured by using reflected light of light irradiated onto the light receiving surface 252, and thereby the end of the thinning of the semiconductor layer 200 can be detected.

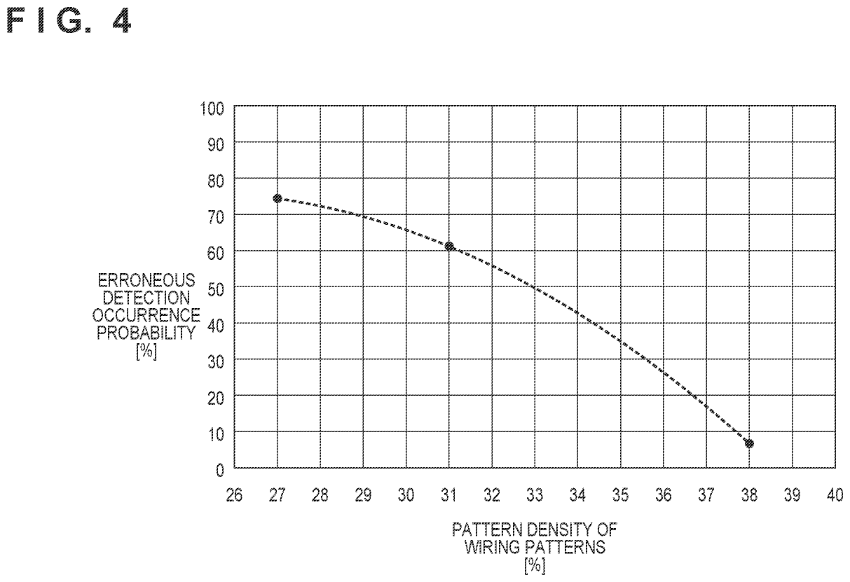

FIG. 5 is a diagram illustrating an arrangement of the plurality of the wiring patterns 601 arranged in the wiring layer 205 which is the closest to the main surface 251 among the plurality of wiring layers 205 and 207 arranged in the main surface 251 of the semiconductor layer 200. FIG. 5 is a plan view of the photoelectric conversion apparatus 930 viewed from the side of the light receiving surface 252 of the semiconductor layer 200. FIG. 5 illustrates the wiring patterns 601 arranged in the peripheral region 1051 among the plurality of wiring patterns 601. In an orthographic projection of the semiconductor layer 200 with respect to the main surface 251, the wiring patterns 601 are arranged so as to fill the peripheral region 1051. At this time, the pattern density of the wiring patterns 601 arranged in the peripheral region 1051 is 35% or more in an arbitrary 100 μm² region of the peripheral region 1051. Here, the pattern density of the wiring patterns 601 arranged in the peripheral region 1051 can be obtained as (the area of the wiring patterns 601 in the peripheral region 1051 in the orthographic projection with respect to the main surface 251 of the semiconductor layer 200)/(the area of the peripheral region 1051 in the orthographic projection with respect to the main surface 251 of the semiconductor layer 200). The peripheral region 1051 may be all regions other than the pixel region 1052 of the semiconductor layer 200, including the opening 232 or the like where the input/output terminals 231 are exposed. Further, the 100 μm² region may be, for example, a region of 10 μm×10 μm or a region of 5 μm×20 μm. Hereinafter, the “pattern density” in which the wiring patterns 601 and the like are arranged means a pattern density in an orthographic projection with respect to the main surface 251 of the semiconductor layer 200.

FIG. 3A is a cross-sectional view illustrating a configuration of a photoelectric conversion apparatus as a comparative example. In the photoelectric conversion apparatus of the comparative example, the wiring patterns arranged in the wiring layer 205 which is the closest to the main surface 251 of the semiconductor layer 200 in the peripheral region 1051 are few (e.g., pattern density is less than 35% in an arbitrary 100 μm² region). In this case, in the process of thinning the semiconductor layer 200, as illustrated in FIG. 3A, a ratio of a spectrum reflected from the wiring layer 207, the conductive layers 211 and 214, and the like, which are more separated from the semiconductor layer 200 than the wiring layer 205, increases. Therefore, the accuracy of monitoring the film thickness of the semiconductor layer 200 is reduced. As a result, the flatness of the light receiving surface 252 of the semiconductor layer 200 and the film thickness uniformity of the semiconductor layer 200 are bad.

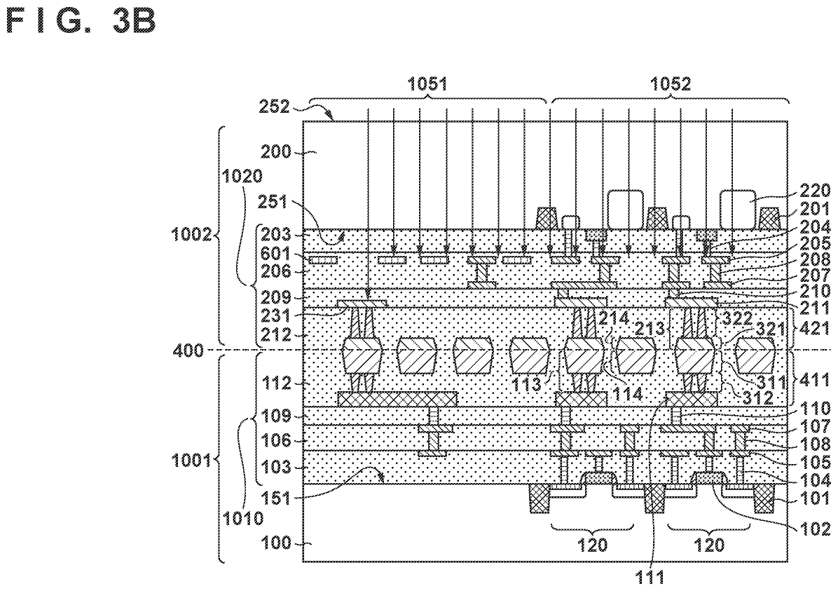

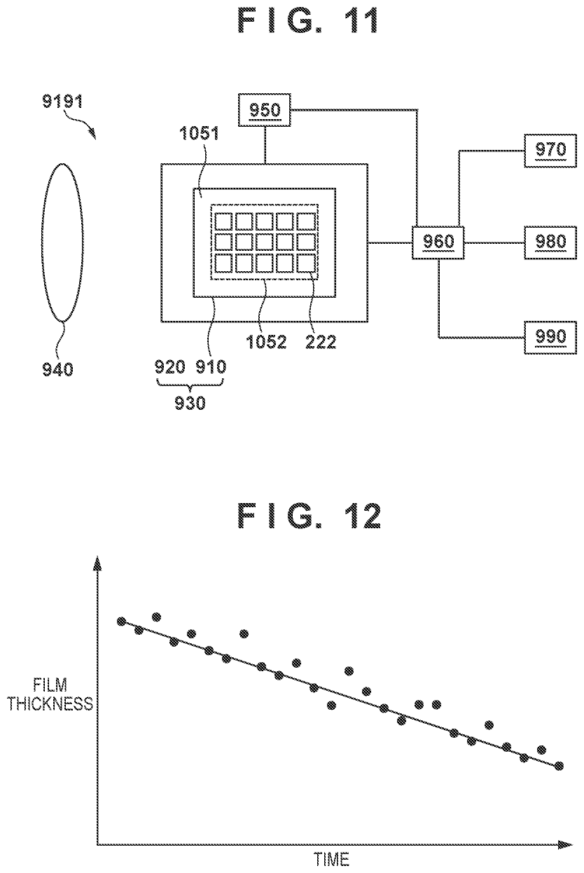

A cross section of the photoelectric conversion apparatus 930 according to the present embodiment is illustrated in FIG. 3B. In the peripheral region 1051, a large number of wiring patterns 601 are arranged in the wiring layer 205 closest to the main surface 251 of the semiconductor layer 200. Therefore, the proportion of the reflection spectrum from the wiring layer 207, the conductive layers 211 and 214, and the like, which are farther from the semiconductor layer 200 than the wiring layer 205, is reduced. FIG. 4 is an erroneous detection occurrence probability in film thickness monitoring where the wiring pattern density of the wiring patterns 601 in the peripheral region 1051 is changed. As illustrated in FIG. 4, the probability of occurrence of erroneous detection in the film thickness monitoring of the semiconductor layer 200 decreases as the pattern density of the wiring patterns 601 increases. For example, by setting the pattern density of the wiring patterns 601 to 35% or more, the erroneous detection occurrence probability becomes 40% or less. The thickness of the semiconductor layer 200 is measured, for example, over a plurality of times as time elapses while thinning a plurality of points in the plane. Therefore, if the erroneous detection is about 40%, it is possible to obtain the change in the film thickness from the state before the thinning of the film thickness of the semiconductor layer 200 by measurement of the film thickness over a plurality of times, and it is possible to accurately control the thickness of the semiconductor layer 200. For example, as illustrated in FIG. 12, measurement results that do not accord with the temporal change can be eliminated as erroneous detection. FIG. 12 is measurement results when the false positive rate is about 40%. The number of times the film thickness is measured as time elapses may be, for example, about 10 times. In addition, in the thinning process, the number of times that the film thickness is measured as time elapses may be several tens or more times (for example, 20 times, 50 times, 100 times, . . . ). Therefore, since the erroneous detection occurrence probability is 40% or less, it is possible to accurately monitor the film thickness of the semiconductor layer 200 as illustrated in FIG. 12. Therefore, it is believed that an erroneous detection includes a lot of reflection spectrum from the wiring layer 207, the conductive layers 211 and 214, and the like, which are farther from the main surface 251 of the semiconductor layer 200 than the wiring layer 205. Therefore, when the number of measurements increases, it is also possible to determine an erroneous detection when the measured film thickness is larger than a trend in temporal change, and it is possible to further increase the accuracy of the monitoring of the film thickness of the semiconductor layer 200. As described above, in the thinning process, it is possible to suppress the worsening of the flatness of the light receiving surface 252 of the semiconductor layer 200 and the worsening of the film thickness uniformity of the semiconductor layer 200 due to a decrease in the monitoring accuracy of the film thickness of the semiconductor layer 200. By this, the characteristics of the photoelectric conversion apparatus 930 in which the plurality of semiconductor layers 100 and 200 are stacked can be improved.

In the present embodiment, the pattern density of the wiring patterns 601 arranged in the wiring layer 205 closest to the main surface 251 of the semiconductor layer 200 is improved. On the other hand, as illustrated in FIG. 3B, in the peripheral region 1051, configuration may be such that the density of the wiring patterns of the wiring layer 207 separated from the main surface of the semiconductor layer 200 is not improved. For example, the pattern densities of each of the wiring layers other than the wiring layer closest to the main surface 251 of the semiconductor layer 200 among the plurality of wiring layers 205 and 207 in the peripheral region 1051 may be 30% or less in an arbitrary 100 μm² region. As a result, it is possible to suppress the load on the blade during a process of trimming the semiconductor component 1002.

Further, for example, the difference between the pattern density in an arbitrary 100 μm² region of the wiring patterns 601 arranged in the pixel region 1052 among the plurality of wiring patterns 601 arranged in the wiring layer 205 which is the closest to the main surface 251 of the semiconductor layer 200, and the pattern density in an arbitrary 100 μm² region of the wiring patterns 601 arranged in the peripheral region 1051 among the plurality of the wiring patterns 601 may be 5% or less. In the pixel region 1052 and the peripheral region 1051, the pattern density of the wiring patterns 601 arranged in the wiring layer 205 which is the closest to the semiconductor layer 200 does not significantly differ. As a result, the signal caused by the wiring patterns 601 arranged in the wiring layer 205 included in the reflection spectrum does not significantly differ between the pixel region 1052 and the peripheral region 1051, and therefore the accuracy of monitoring the film thickness of the semiconductor layer 200 can be stabilized. In addition, variations in thinning caused by a density difference between the underlying patterns of the pixel region 1052 and the peripheral region 1051 can be suppressed.

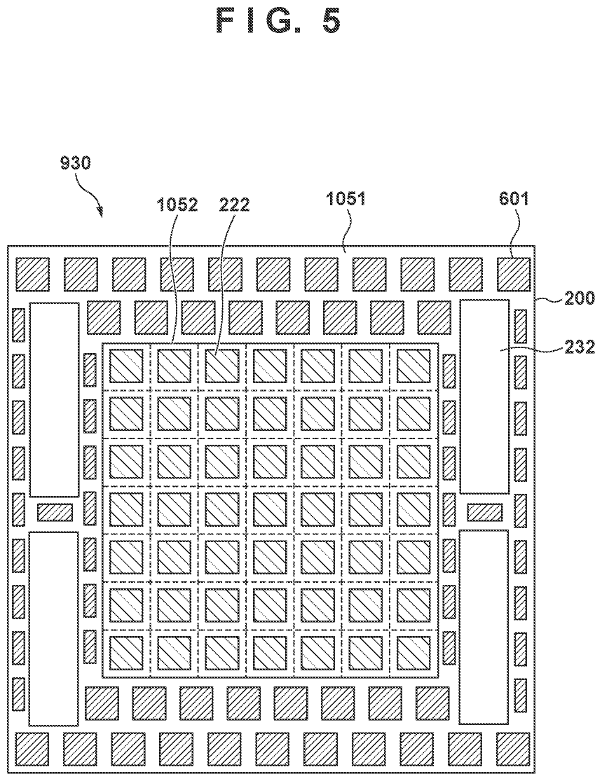

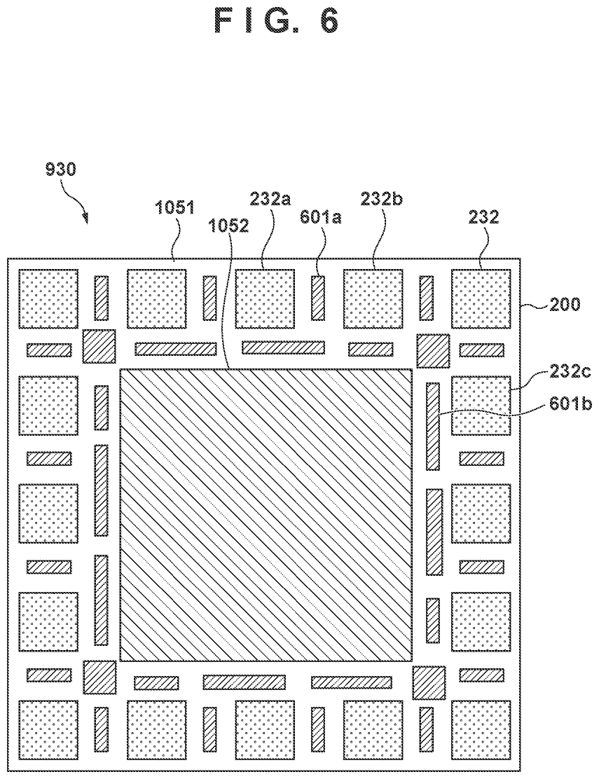

Next, an example of arrangement of the wiring patterns 601 will be described with reference to FIG. 6 and FIG. 7. FIG. 6 is a diagram illustrating an arrangement of the plurality of the wiring patterns 601 arranged in the wiring layer 205 which is the closest to the main surface 251 among the plurality of wiring layers 205 and 207 arranged in the main surface 251 of the semiconductor layer 200, and is a plan view when the photoelectric conversion apparatus 930 is seen from the side of the light receiving surface 252 of the semiconductor layer 200. FIG. 6 illustrates the wiring patterns 601 arranged in the peripheral region 1051 among the plurality of wiring patterns 601.

In the configuration illustrated in FIG. 6, in an orthographic projection of the semiconductor layer 200 with respect to the main surface 251, the plurality of wiring patterns 601 arranged in the wiring layer 205 which is the closest to the main surface 251 of the semiconductor layer 200 includes a wiring pattern 601a arranged between two openings 232a and 232b which are adjacent to each other among the plurality of openings 232 each for exposing the input/output terminals 231. In such a case, a distance between each of the two openings 232a and 232b and the wiring pattern 601a may be 3 μm or less.

FIG. 7 is a diagram illustrating an erroneous detection occurrence probability when the distance between the openings 232a and 232b for exposing the input/output terminals 231 and the wiring pattern 601a is changed in a predetermined wiring pattern. As illustrated in FIG. 7, the false positive occurrence probability when monitoring the thickness of the semiconductor layer 200 decreases as the distance between the openings 232a and 232b and the wiring pattern 601a decreases. This is because the pattern density of the wiring patterns 601 in the peripheral region 1051 increases as the distance between the openings 232a and 232b and the wiring pattern 601a decreases. By setting the distance between the openings 232a and 232b and the wiring pattern 601a to be equal to or less than 3.0 μm, the erroneous detection occurrence probability becomes 40% or less, and the thickness of the semiconductor layer 200 in the thinning process can be controlled with high accuracy. As a result, the characteristics of the photoelectric conversion apparatus 930 can be improved.

Here, the wiring pattern 601a may be a dummy pattern. The dummy pattern may be, for example, a floating wiring pattern that is not connected to another wiring pattern. The dummy pattern may be, for example, a wiring pattern in which one end is connected to a signal line or the like, but the other end is not connected to another wiring pattern or the like. The dummy pattern may be a pattern that is not used for applications such as signal transmission and power supply. A dummy pattern is arranged as the wiring patterns 601 in a region where there are few wiring patterns used for signal transmission, power supply, or the like. As a result, as described above, the thickness of the semiconductor layer 200 in the thinning process can be accurately controlled.

In the configuration illustrated in FIG. 6, in an orthographic projection of the semiconductor layer 200 with respect to the main surface 251, the plurality of wiring patterns 601 arranged in the wiring layer 205 which is the closest to the main surface 251 of the semiconductor layer 200 includes the wiring pattern 601b which is arranged between opening 232c which is arranged to be adjacent to the pixel region 1052 among the plurality of the openings 232 each for exposing the input/output terminals 231 and the pixel region 1052. In such a case, a distance between each of the opening 232c and the pixel region 1052 and the wiring pattern 601b may be 3 μm or less. As a result, the pattern density of the wiring patterns 601 arranged in the wiring layer 205 in the peripheral region 1051 is improved, and the thickness of the semiconductor layer 200 can be controlled in the thinning process with high accuracy. Similarly to what was described above, the wiring pattern 601b may be a dummy pattern.

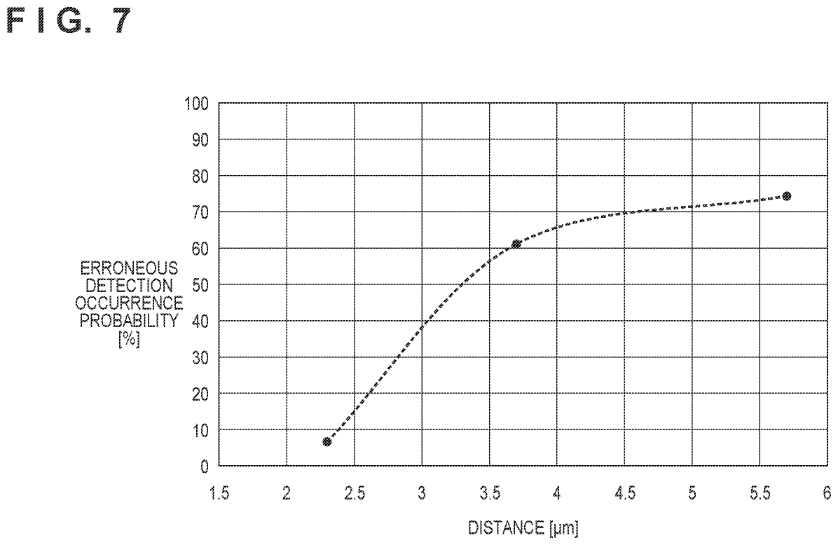

Next, another example of arrangement of the wiring patterns 601 will be described with reference to FIG. 8. FIG. 8 is a diagram illustrating an arrangement of the plurality of the wiring patterns 601 arranged in the wiring layer 205 which is the closest to the main surface 251 among the plurality of wiring layers 205 and 207 arranged in the main surface 251 of the semiconductor layer 200, and is a plan view when the photoelectric conversion apparatus 930 is seen from the side of the light receiving surface 252 of the semiconductor layer 200. FIG. 8 illustrates the wiring patterns 601 arranged in the peripheral region 1051 among the plurality of wiring patterns 601.

As illustrated in FIG. 8, the peripheral region 1051 may include a circuit region 701 in which a driving circuit for driving a plurality of pixels including each of the photoelectric conversion elements 222 arranged in the pixel region 1052 is arranged. In the circuit region 701, a plurality of transistors and the like are arranged on the main surface 251 of the semiconductor layer 200. In such a case, in an orthographic projection of the semiconductor layer 200 with respect to the main surface 251, the plurality of wiring patterns 601 arranged in the wiring layer 205 which is the closest to the main surface 251 of the semiconductor layer 200 includes a wiring pattern 601c arranged between an opening 232d arranged to be adjacent to the circuit region 701a among the plurality of openings 232 each for exposing the input/output terminals 231 and a circuit region 701a. In such a case, a distance between each of the opening 232d and the circuit region 701a and the wiring pattern 601c may be 3 μm or less. As a result, the pattern density of the wiring patterns 601 arranged in the wiring layer 205 in the peripheral region 1051 is improved, and the thickness of the semiconductor layer 200 can be controlled in the thinning process with high accuracy. Similarly to what was described above, the wiring pattern 601c may be a dummy pattern.

As illustrated in FIG. 8, in an orthographic projection of the semiconductor layer 200 with respect to the main surface 251, the plurality of wiring patterns 601 arranged in the wiring layer 205 which is the closest to the main surface 251 of the semiconductor layer 200 include a wiring pattern 601d which is arranged between the pixel region 1052 and a circuit region 701b. In such a case, a distance between each of the pixel region 1052 and the circuit region 701b and the wiring pattern 601d may be 3 μm or less. As a result, the pattern density of the wiring patterns 601 arranged in the wiring layer 205 in the peripheral region 1051 is improved, and the thickness of the semiconductor layer 200 can be controlled in the thinning process with high accuracy. Similarly to what was described above, the wiring pattern 601d may be a dummy pattern.

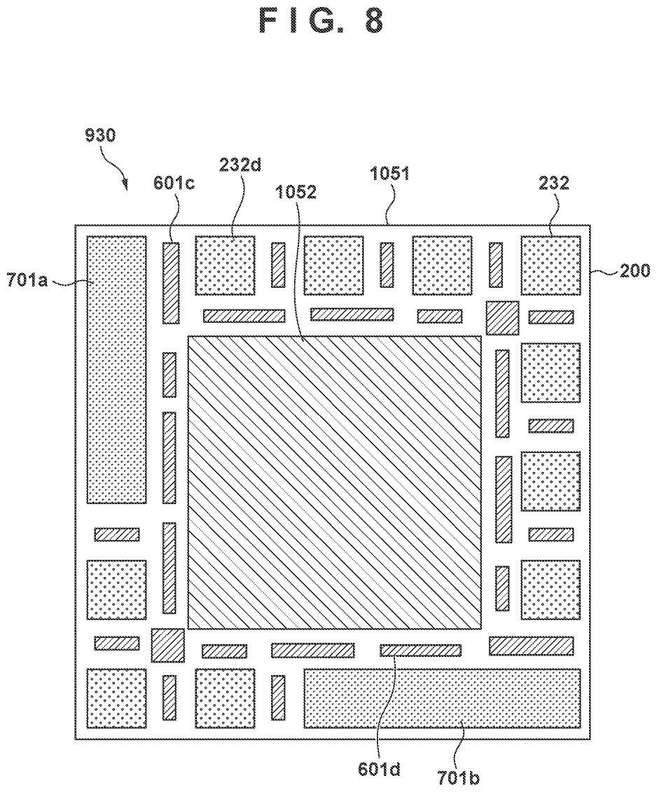

Next, another example of arrangement of the wiring patterns 601 will be described with reference to FIG. 9. FIG. 9 is a diagram illustrating an arrangement of the plurality of the wiring patterns 601 arranged in the wiring layer 205 which is the closest to the main surface 251 among the plurality of wiring layers 205 and 207 arranged in the main surface 251 of the semiconductor layer 200, and is a plan view when the photoelectric conversion apparatus 930 is seen from the side of the light receiving surface 252 of the semiconductor layer 200. FIG. 9 illustrates the wiring patterns 601 arranged in the peripheral region 1051 among the plurality of wiring patterns 601.

As illustrated in FIG. 9, in an orthographic projection of the semiconductor layer 200 with respect to the main surface 251, the plurality of wiring patterns 601 arranged in the wiring layer 205 which is the closest to the main surface 251 of the semiconductor layer 200 include a wiring pattern 601e which is arranged along the outer edge of the semiconductor layer 200. In this case, in an orthographic projection of the main surface of the semiconductor layer 200, the distance between the outer edge of the semiconductor layer 200 and the wiring pattern 601e may be 3 μm or less. In addition, in the orthographic projection of the semiconductor layer 200 with respect to the main surface 251, the wiring pattern 601e may be in contact with the outer edge of the semiconductor layer 200. As a result, the pattern density of the wiring patterns 601 arranged in the wiring layer 205 in the peripheral region 1051 is improved, and the thickness of the semiconductor layer 200 can be controlled in the thinning process with high accuracy. Further, in the orthographic projection of the semiconductor layer 200 with respect to the main surface, the distance between the wiring pattern 601e and an opening 232e adjacent to the wiring pattern 601 may be 3 μm or less. As a result, the pattern density of the wiring patterns 601 can be further improved. Similarly to what was described above, the wiring pattern 601e may be a dummy pattern.

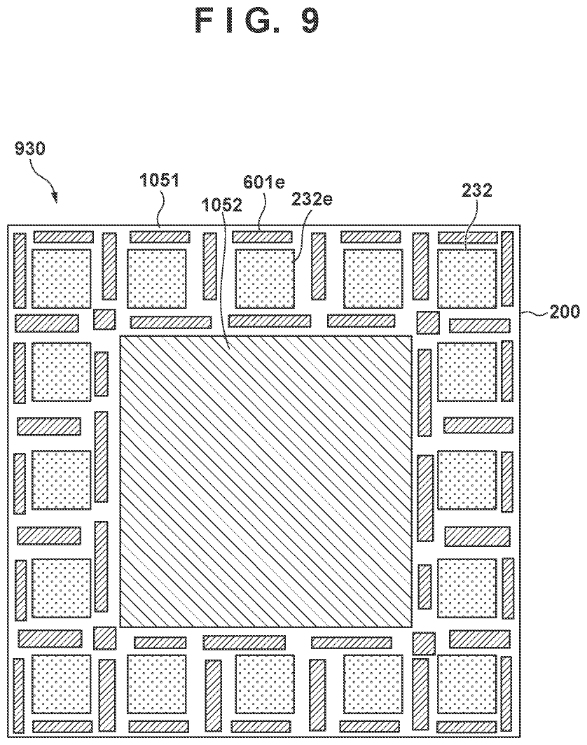

Incidentally, as illustrated in FIGS. 10A and 10B, when the photoelectric conversion apparatus 930 is manufactured, a plurality of pixel regions 1052 may be arranged in the semiconductor layer 200. Therefore, a process of cutting the semiconductor layer 200 in which the plurality of pixel regions 1052 are arranged in a scribe region 1053 and dicing it into chips (the photoelectric conversion apparatus 930) each including a pixel region 1052 may be included. The process of dicing may be performed after thinning the semiconductor layer 200. Therefore, the pattern density of the wiring patterns 601 arranged in the wiring layer 205 which is the closest to the main surface 251 of the semiconductor layer 200 in the scribe region 1053 may be evaluated.

That is, prior to the dicing process, the plurality of wiring patterns 601 arranged in the wiring layer 205 which is closest to the main surface 251 of the semiconductor layer 200 may include wiring patterns 601f arranged in the scribe region 1053. In such a case, prior to the dicing process, pattern density of wiring patterns 601f arranged in a scribe region 1053 among the plurality of wiring patterns 601 arranged in the wiring layer 205 closest to the main surface 251 of the semiconductor layer 200 may be 35% or more in an arbitrary 100 μm² region. As a result, the pattern density of the wiring patterns 601 arranged in the wiring layer 205 in the scribe region 1053 is improved, and the thickness of the semiconductor layer 200 can be controlled in the thinning process with high accuracy.

Also, prior to the dicing process, the plurality of wiring patterns 601 arranged in the wiring layer 205 which is the closest to the main surface 251 of the semiconductor layer 200 may include wiring patterns 601 which are arranged to straddle adjacent chips (the photoelectric conversion apparatus 930). Here, the scribe region 1053 after dicing may constitute a part of the peripheral region 1051. Therefore, in this case, after dicing, a wiring pattern 601 may be in contact with the outer edge of the semiconductor layer 200.

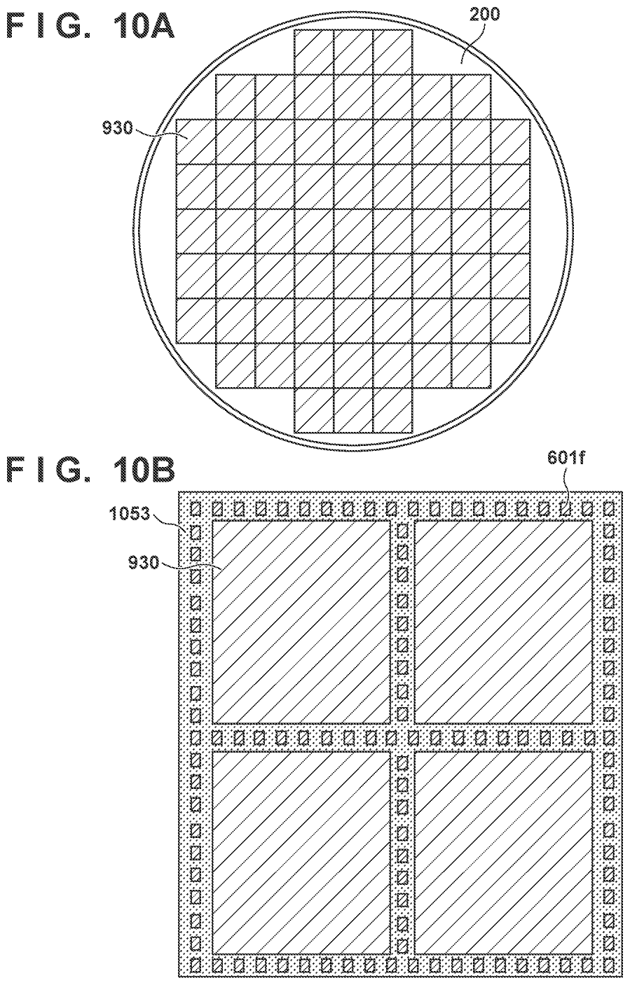

An application example of the photoelectric conversion apparatus 930 of the present embodiment will be described with reference to FIG. 11. FIG. 11 is a schematic diagram of a device 9191 including the photoelectric conversion apparatus 930. The photoelectric conversion apparatus 930, in addition to a semiconductor device 910 including the semiconductor component 1001 and the semiconductor component 1002 described above, may include a package 920 that houses the semiconductor device 910, but configuration may be such that the photoelectric conversion apparatus 930 does not include the package 920. The semiconductor layer 100 and the semiconductor layer 200 are included in the semiconductor device 910. In the present embodiment, the photoelectric conversion apparatus 930 is a so-called image capturing apparatus. The semiconductor device 910 comprises the pixel region 1052 in which the photoelectric conversion elements 222 are arranged in a matrix, and the peripheral region 1051 in the periphery thereof. The peripheral region 1051 can be provided with a peripheral circuit and an input/output terminal 231. The device 9191 may include at least one of an optical apparatus 940, a control apparatus 950, a processing apparatus 960, a display apparatus 970, a storage apparatus 980, and a mechanical apparatus 990.

Hereinafter, the device 9191 including the photoelectric conversion apparatus 930 illustrated in FIG. 11 will be described in detail. The photoelectric conversion apparatus 930, in addition to the semiconductor device 910 including the semiconductor layer 100 described above, may include the package 920 which houses the semiconductor device 910. The package 920 may include a base body to which the semiconductor device 910 is fixed, and a lid body such as glass facing the semiconductor device 910. The package 920 may further include a bonding member such as a bonding wire or a bump that connects a terminal provided on the substrate and a terminal provided on the semiconductor device 910.

The device 9191 may include at least one of the optical apparatus 940, the control apparatus 950, the processing apparatus 960, the display apparatus 970, the storage apparatus 980, and the mechanical apparatus 990. The optical apparatus 940 corresponds to the photoelectric conversion apparatus 930. The optical apparatus 940 is, for example, a lens, a shutter, or a mirror. The control apparatus 950 controls the photoelectric conversion apparatus 930. The control apparatus 950 is, for example, a semiconductor apparatus such as an ASIC.

The processing apparatus 960 processes a signal outputted from the photoelectric conversion apparatus 930. The processing apparatus 960 is a semiconductor apparatus such as a CPU or an ASIC for constituting an AFE (analog front end) or a DFE (digital front end). The display apparatus 970 is an EL display apparatus or a liquid crystal display apparatus that displays information (images) obtained by the photoelectric conversion apparatus 930. The storage apparatus 980 is a magnetic device or a semiconductor device that stores information (images) obtained by the photoelectric conversion apparatus 930. The storage apparatus 980 is a volatile memory such as an SRAM or a DRAM, or a nonvolatile memory such as a flash memory or a hard disk drive.

The mechanical apparatus 990 includes a movable portion such as a motor or an engine, or a propulsion portion. In the device 9191, a signal outputted from the photoelectric conversion apparatus 930 is displayed on the display apparatus 970 or transmitted to the outside by a communication apparatus (not illustrated) included in the device 9191. For this, the device 9191 may further comprise the storage apparatus 980 and the processing apparatus 960 separately from the storage circuit and the arithmetic circuit included in the photoelectric conversion apparatus 930. The mechanical apparatus 990 may be controlled based on a signal outputted from the photoelectric conversion apparatus 930.

The device 9191 is suitable for an electronic device such as an information terminal (for example, a smartphone or a wearable terminal) having a capture function or a camera (for example, an interchangeable lens camera, a compact camera, a video camera, or a surveillance camera). The mechanical apparatus 990 in the camera may drive components of the optical apparatus 940 for zooming, focusing, and shutter operations. Alternatively, the mechanical apparatus 990 in the camera may move the photoelectric conversion apparatus 930 for an image stabilization operation.

In addition, the device 9191 may be a transport device such as a vehicle, a ship, or an airplane. The mechanical apparatus 990 in the transportation equipment may be used as a moving apparatus. The device 9191 serving as a transportation device is suitable for transporting the photoelectric conversion apparatus 930 or for assisting and/or automating driving (steering) by an image capture function. The processing apparatus 960 for assisting and/or automating driving (steering) can perform processing for operating the mechanical apparatus 990 as a moving apparatus based on information obtained by the photoelectric conversion apparatus 930. Alternatively, the device 9191 may be a medical device such as an endoscope, a measurement device such as a distance measuring sensor, an analytical device such as an electron microscope, or an office device such as a copying machine.

The embodiments described above can be appropriately modified without departing from the technical idea. The disclosure of the present specification includes not only the description in the present specification but also all matters that can be understood from the present specification and the drawings attached to the present specification. The content disclosed in this specification includes a complementary set of concepts described in this specification. That is, for example, if there is a description in this specification that “A is B”, even if the description that “A is not B” is omitted, the present specification should be treated as disclosing “A is not B”. This is because the case where “A is B” is being described is premised upon the fact that the case where “A is not B” is being considered.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-143101, filed Sep. 8, 2022, which is hereby incorporated by reference herein in its entirety.

What is claimed is:

1. A photoelectric conversion apparatus comprising a semiconductor layer that includes a pixel region in which a plurality of pixels each comprising a photoelectric conversion element are arranged, wherein
a plurality of wiring layers are arranged on a side of a main surface on the opposite side to a light receiving surface of the semiconductor layer,
a plurality of wiring patterns are arranged in a wiring layer closest to the main surface among the plurality of wiring layers, and
a pattern density of the wiring patterns arranged in a peripheral region between the pixel region and an outer edge of the semiconductor layer among the plurality of wiring patterns is 35% or more in an arbitrary 100 μm² region of the peripheral region.

2. The photoelectric conversion apparatus according to claim 1, wherein a pattern density of each of the wiring layers other than the wiring layer closest to the main surface among the plurality of wiring layers in the peripheral region is 30% or less in an arbitrary 100 μm² region.

3. The photoelectric conversion apparatus according to claim 1, wherein a difference between the pattern density in an arbitrary 100 μm² region of the wiring patterns arranged in the pixel region among the plurality of wiring patterns and a pattern density in an arbitrary 100 μm² region of the wiring patterns arranged in the peripheral region of the plurality of wiring patterns is 5% or less.

4. The photoelectric conversion apparatus according to claim 1, wherein
a plurality of input/output terminals for electrically connecting the photoelectric conversion apparatus and an external device are arranged in the peripheral region,
a plurality of openings for exposing the plurality of input/output terminals are arranged in the semiconductor layer, and
in an orthographic projection with respect to the main surface, the plurality of wiring patterns comprise a first wiring pattern arranged between two adjacent openings in the plurality of openings.

5. The photoelectric conversion apparatus according to claim 4, wherein a distance between each of the two openings and the first wiring pattern is 3 μm or less.

6. The photoelectric conversion apparatus according to claim 4, wherein the first wiring pattern is a dummy pattern.

7. The photoelectric conversion apparatus according to claim 4, wherein in the orthographic projection with respect to the main surface, the plurality of wiring patterns include a second wiring pattern arranged between a first opening arranged to be adjacent to the pixel region among the plurality of openings and the pixel region.

8. The photoelectric conversion apparatus according to claim 7, wherein in the orthographic projection with respect to the main surface, a distance between each of the first opening and the pixel region and the second wiring pattern is 3 μm or less.

9. The photoelectric conversion apparatus according to claim 7, wherein the second wiring pattern is a dummy pattern.

10. The photoelectric conversion apparatus according to claim 4, wherein
the peripheral region comprises a circuit region in which a driving circuit for driving the pixel region is arranged,
in the orthographic projection with respect to the main surface, the plurality of wiring patterns include a third wiring pattern arranged between a second opening arranged to be adjacent to the circuit region in the plurality of openings and the circuit region.

11. The photoelectric conversion apparatus according to claim 10, wherein in the orthographic projection with respect to the main surface, a distance between each of the second opening and the circuit region and the third wiring pattern is 3 μm or less.

12. The photoelectric conversion apparatus according to claim 10, wherein the third wiring pattern is a dummy pattern.

13. The photoelectric conversion apparatus according to claim 1, wherein
in an orthographic projection with respect to the main surface, the plurality of wiring patterns includes a fourth wiring pattern arranged along the outer edge, and
in the orthographic projection with respect to the main surface, a distance between the outer edge and the fourth wiring pattern is 3 μm or less.

14. The photoelectric conversion apparatus according to claim 13, wherein in the orthographic projection with respect to the main surface, the fourth wiring pattern is in contact with the outer edge.

15. The photoelectric conversion apparatus according to claim 13, wherein the fourth wiring pattern is a dummy pattern.

16. A device, comprising:
the photoelectric conversion apparatus according to claim 1; and
a processing apparatus configured to process a signal outputted from the photoelectric conversion apparatus.

17. A method for manufacturing a photoelectric conversion apparatus, the method comprising:
preparing a semiconductor layer comprising a pixel region in which a plurality of pixels each including a photoelectric conversion element are arranged;
thinning the semiconductor layer from a side of a light receiving surface on an opposite side to a main surface where a plurality of wiring layers are arranged,
wherein
a plurality of wiring patterns are arranged in a wiring layer closest to the main surface among the plurality of wiring layers,
in the thinning, a film thickness of the semiconductor layer is measured by using reflected light of light irradiated onto the light receiving surface, and
a pattern density of the wiring patterns arranged in a peripheral region between the pixel region and an outer edge of the semiconductor layer among the plurality of wiring patterns is 35% or more in an arbitrary 100 μm² region of the peripheral region.

18. The method for manufacturing according to claim 17, wherein
in the preparing, a plurality of pixel regions including the pixel region are arranged in the semiconductor layer,
the method further comprises cutting the semiconductor layer in a scribe region, and dicing into chips each comprising a pixel region, and
prior to the dicing, the plurality of wiring patterns includes a wiring pattern arranged in the scribe region.

19. The method for manufacturing according to claim 18, wherein prior to the dicing, a pattern density of the wiring pattern arranged in the scribe region among the plurality of wiring patterns is 35% or more in an arbitrary 100 μm² region.

20. The method for manufacturing according to claim 18, wherein prior to the dicing, the plurality of wiring patterns includes a wiring pattern arranged to straddle adjacent chips.
